(19) United States
(12) Patent Application Publication
(10) Pub. No.: US 2026/0319316 A1
(43) Pub. Date: Oct. 15, 2026

(54) FLEXIBLE DISPLAY COVER PLATE AND METHOD FOR MANUFACTURING SAME, DISPLAYING MODULE, AND DISPLAY DEVICE

(71) Applicant: BOE Technology Group Co., Ltd., Beijing (CN)

(72) Inventors: Yonghong ZHOU, Beijing (CN); Ziang HAN, Beijing (CN); Zhao LI, Beijing (CN); Shiming SHI, Beijing (CN); Song ZHANG, Beijing (CN); Zihan GAO, Beijing (CN)

(21) Appl. No.: 19/481,140

(22) PCT Filed: Nov. 6, 2024
(86) PCT No.: PCT/CN2024/130296

§ 371 Date: Nov. 3, 2025

(30) Foreign Application Priority Data
Dec. 20, 2023 (CN) 202311767443.9

(51) Int. Cl. G02F 1/16753; G02F 1/167

(52) U.S. Cl. CPC G02F 1/16753; G02F 1/167

(57) ABSTRACT

Provided is a flexible display cover plate. The flexible display cover plate includes a first cover plate layer and a second cover plate layer that are stacked along a first direction, wherein an orthographic projection of the second cover plate layer on the first cover plate layer completely covers the first cover plate layer; and the second cover plate layer comprises a view region and a non-view region, the non-view region being disposed around the view region, and the non-view region comprising an ink region and a non-ink region, wherein the ink region is disposed between the non-ink region and the view region, and there is an overlapping are between an orthographic projection of the non-ink region on the first cover plate layer and the first cover plate layer.

### CROSS-REFERENCE TO RELATED APPLICATIONS

The present disclosure is a U.S. national phase application based on PCT/CN2024/130296, filed on Nov. 6, 2024, which claims priority to Chinese Patent Application No. 202311767443.9 filed on Dec. 20, 2023, and entitled “FLEXIBLE DISPLAY COVER PLATE, DISPLAYING MODULE, AND DISPLAY DEVICE”, both of which are incorporated by reference herein.

### TECHNICAL FIELD

The present disclosure relates to the field of display technologies, and in particular, relates to a flexible display cover plate and a method for manufacturing the same, a displaying module, and a display device.

### BACKGROUND

With the progress of display technologies, flexible display devices, with their deformable and foldable characteristics, have become display devices with highly promising application scenarios in the current display field. The flexible display device includes a flexible display cover plate. The flexible display cover plate has strong strength and impact resistance, and can protect the internal structure of the flexible display device, preventing the internal structure of the flexible display device from external damage. The current flexible display cover plate usually includes ultra-thin glass (UTG).

### SUMMARY

The present disclosure provides a flexible display cover plate and a method for manufacturing the same, a displaying module, and a display device.

In one aspect, a flexible display cover plate is provided. The flexible display cover plate includes:
a first cover plate layer and a second cover plate layer that are stacked along a first direction, wherein an orthographic projection of the second cover plate layer on the first cover plate layer completely covers the first cover plate layer; and
the second cover plate layer includes a view region and a non-view region, the non-view region being disposed around the view region, and the non-view region includes an ink region and a non-ink region,
wherein the ink region is disposed between the non-ink region and the view region, and there is an overlapping area between an orthographic projection of the non-ink region on the first cover plate layer and the first cover plate layer.

In some embodiments, the non-view region includes a first side edge region, wherein the first side edge region includes the non-ink region, and there is a first overlapping area between an orthographic projection, on the first cover plate layer, of the non-ink region in the first side edge region and the first cover plate layer; and
a dimension L1 of the non-ink region in the first side edge region in a second direction satisfies: 0.5 millimeters (mm)≤L1≤20 mm, and a dimension L2 of the first overlapping area in a third direction satisfies: 0 mm<L2≤1 mm,
wherein the second direction is a length direction of the first side edge region, the third direction is a width direction of the first side edge region, and any two of the first direction, the second direction, and the third direction are perpendicular to each other.

In some embodiments, the first side edge region includes a plurality of said non-ink regions, the plurality of non-ink regions in the first side edge region being spaced apart at equal intervals along the second direction.

In some embodiments, a ratio of a total dimension of the plurality of non-ink regions in the first side edge region in the second direction to a length of the first side edge region ranges from 0.1 to 0.5.

In some embodiments, the non-view region further includes a second side edge region adjacent to the first side edge region, wherein a length direction of the second side edge region is the third direction, a width direction of the second side edge region is the second direction, the second side edge region includes the non-ink region, and there is a second overlapping area between an orthographic projection, on the first cover plate layer, of the non-ink region in the second side edge region and the first cover plate layer; and
a dimension L3 of the non-ink region in the second side edge region in the third direction satisfies: 0.5 mm≤L3≤20 mm, and a dimension L4 of the second overlapping area in the second direction satisfies: 0 mm<L4≤1 mm.

In some embodiments, the second side edge region includes a plurality of non-ink regions, the plurality of non-ink regions in the second side edge region being spaced apart at equal intervals along the third direction.

In some embodiments, a ratio of a total dimension of the plurality of non-ink regions in the second side edge region in the third direction to a length of the second side edge region ranges from 0.1 to 0.5.

In some embodiments, the non-ink region is disposed on the second cover plate layer at a position where a side edge spacing from the first cover plate layer is minimal.

In some embodiments, a distance from the non-ink region to a vertex of the second cover plate layer is less than a preset distance.

In some embodiments, the flexible display cover plate is provided with a bending region, and the non-ink region is disposed in a region other than the bending region.

In some embodiments, the non-view region includes a lead-out side edge region, the lead-out side edge region being configured to connect to a lead-out region of a display device.

In some embodiments, the non-view region includes a non-lead-out side edge region, wherein a side edge spacing between the non-lead-out side edge region and the first cover plate layer ranges from 0.05 mm to 1 mm, and the non-ink region is disposed in the non-lead-out side edge region.

In some embodiments, the flexible display cover plate further includes an adhesive layer, the adhesive layer being disposed between the first cover plate layer and the second cover plate layer.

In some embodiments, a shape of the non-ink region includes at least one of a rectangle, a circle, an ellipse, a rhombus, or a trapezoid.

In some embodiments, a manufacturing material of the first cover plate layer includes ultra-thin glass.

In another aspect, a method for manufacturing a flexible display cover plate is provided. The method is applicable to manufacturing the flexible display cover plate as defined in any one of the above aspects. The method includes:
obtaining a flexible display cover plate motherboard by stacking a first cover plate layer and a second cover plate layer along a first direction, wherein an orthographic projection of the second cover plate layer on the first cover plate layer completely covers the first cover plate layer, the second cover plate layer includes a view region and a non-view region, the non-view region is disposed around the view region, and the non-view region includes an ink region and a non-ink region, wherein the ink region is disposed between the non-ink region and the view region, and there is an overlapping area between an orthographic projection of the non-ink region on the first cover plate layer and the first cover plate layer; and
obtaining a flexible display cover plate by cutting the flexible display cover plate motherboard along a cutting line, wherein the cutting line is in the non-view region, and the cutting line passes through the non-ink region.

In some embodiments, before stacking the first cover plate layer and the second cover plate layer along the first direction, the method further includes:
providing a cover plate motherboard;
forming an ink layer on the cover plate motherboard; and
forming a window in the ink layer on the cover plate motherboard to form the ink region and the non-ink region, thereby obtaining the first cover plate layer.

In yet another aspect, a displaying module is provided. The displaying module includes the flexible display cover plate as defined in any one of the above aspects.

In some embodiments, the displaying module further includes a display substrate, wherein
the flexible display cover plate is disposed on the display substrate, and one surface, distal to the second cover plate layer, of the first cover plate layer in the flexible display cover plate is attached to the display substrate.

In still another aspect, a display device is provided. The display device includes the displaying module as defined in any one of the above aspects.

### BRIEF DESCRIPTION OF DRAWINGS

FIG. 1 is a schematic structural diagram of a flexible display cover plate according to some embodiments of the present disclosure;

FIG. 2 is a schematic structural diagram of a flexible display cover plate according to some embodiments of the present disclosure;

FIG. 3 is a schematic structural diagram of another flexible display cover plate according to some embodiments of the present disclosure;

FIG. 4 is a schematic structural diagram of yet another flexible display cover plate according to some embodiments of the present disclosure;

FIG. 5 is a schematic structural diagram of still another flexible display cover plate according to some embodiments of the present disclosure;

FIG. 6 is a schematic structural diagram of a flexible display cover plate according to some embodiments of the present disclosure;

FIG. 7 is a schematic structural diagram of another flexible display cover plate according to some embodiments of the present disclosure;

FIG. 8 is a schematic structural diagram of yet another flexible display cover plate according to some embodiments of the present disclosure;

FIG. 9 is a schematic structural diagram of a flexible display cover plate according to some embodiments of the present disclosure;

FIG. 10 is a schematic structural diagram of another flexible display cover plate according to some embodiments of the present disclosure;

FIG. 11 is a schematic flowchart of a method for manufacturing a flexible display cover plate according to some embodiments of the present disclosure;

FIG. 12 is a schematic structural diagram of a displaying module according to some embodiments of the present disclosure; and

FIG. 13 is a schematic structural diagram of a displaying module according to some embodiments of the present disclosure.

### DETAILED DESCRIPTION

For clearer descriptions of the objectives, technical solutions, and advantages of the present disclosure, embodiments of the present disclosure are further described in detail hereinafter with reference to the accompanying drawings.

The “ranges” disclosed in the present disclosure are defined with lower and upper limits. A given range is defined by selecting a lower limit and an upper limit that delineate the boundaries of a particular range. Ranges defined in this manner include endpoint values and can be arbitrarily combined. That is, any lower limit may be combined with any upper limit to form a range. For example, in the case that ranges of 60 to 120 and 80 to 110 are listed for a particular parameter, it is understood that ranges of 60 to 110 and 80 to 120 are also anticipated. Moreover, in the case that the minimum range values of 1 and 2 are listed, and the maximum range values of 3, 4, and 5 are listed, the following ranges can all be anticipated: 1 to 3, 1 to 4, 1 to 5, 2 to 3, 2 to 4, and 2 to 5. In the present disclosure, unless otherwise specified, the numerical range “a to b” indicates an abbreviated representation of any combination of real numbers between a and b, where a and b are both real numbers. For example, the numerical range of “0 to 5” indicates that all real numbers between “0 and 5” have been listed herein, and “0 to 5” is only an abbreviated representation of a combination of these numerical values. In addition, in the case of stating that a parameter is an integer≥2, it is equivalent to disclosing that the parameter is, for example, an integer of 2, 3, 4, 5, 6, 7, 8, 9, 10, 11, 12, or the like.

Unless otherwise specified, all embodiments and optional embodiments of the present disclosure can be combined with each other to form new technical solutions.

Unless otherwise specified, all technical features and optional technical features of the present disclosure can be combined with each other to form new technical solutions.

Terms used in the following embodiments are merely intended to describe specific embodiments, but are not intended to limit the present disclosure. As used in the specification and appended claims of the present disclosure, singular expressions “one”, “a”, “the”, “the above”, “this”, and “the one” are also intended to include expressions such as “one or more”, unless the context clearly indicates to the contrary. It should be further understood that in the following embodiments of the present disclosure, “at least one” and “one or more” mean one, two, or more. The term “and/or” is used to describe an association relationship between associated objects and indicates that three relationships may be present. For example, A and/or B may indicate that: only A is present, both A and B are present, and only B is present, where A and B may be singular or plural. The symbol “/” generally indicates an “or” relationship between the associated objects.

Reference to “an embodiment”, “some embodiments”, “one embodiment”, or the like described in this specification means that one or more embodiments of the present disclosure include a specific feature, structure, or characteristic described with reference to the embodiments. Therefore, statements such as “in an embodiment”, “in some embodiments”, “in other embodiments”, and “in some other embodiments” that appear in different places in this specification do not necessarily mean reference to the same embodiment, but mean reference to “one or more but not all of embodiments”, unless otherwise specifically emphasized in another manner. The terms “include”, “comprise”, “have”, and their variants all mean “include but are not limited to”, unless otherwise specifically emphasized in another manner.

With reference to the accompanying drawings, a flexible display cover plate according to some embodiments of the present disclosure is described in detail below by specific embodiments and application scenarios thereof.

Advances in display technologies enable smart terminal products to feature foldable functions. Such terminal products with foldable functions are also referred to as flexible terminal products. The structure of a flexible terminal product, for example, an electronic device like a smartphone or a tablet computer, includes a flexible display cover plate. The flexible display cover plate has a foldable function, allowing the entire flexible terminal product to be bent or folded.

Ultra-thin glass (UTG) is widely used in the flexible display cover plate because of its good flexibility, smooth touch, and good uniformity. Due to the thin thickness, the UTG is prone to breakage in the assembly process of the flexible display cover plate. In addition, after the flexible display cover plate is assembled, the laser cutting usually needs to be performed on the entire flexible display cover plate, to complete the production and assembly of a subsequent product. However, in the process of performing the laser cutting on the flexible display cover plate, due to the requirements of the production process, a cutting edge is usually proximal to the UTG. Therefore, it is very likely that the UTG is cut, causing damage to the UTG, and further affecting the display effect of the display device.

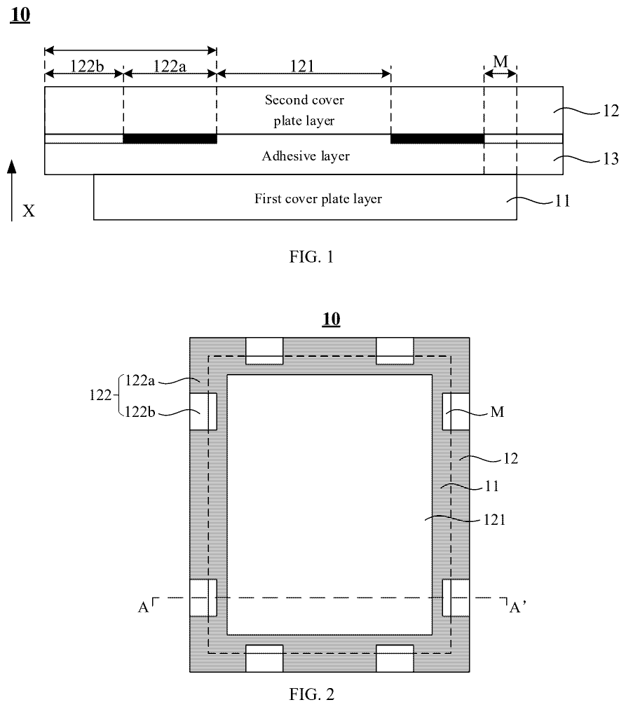

The embodiments of the present disclosure provide a flexible display cover plate. For example, FIGS. 1 and 2 are schematic structural diagrams of a flexible display cover plate according to some embodiments of the present disclosure, respectively. FIG. 1 is a schematic cross-sectional diagram of the flexible display cover plate illustrated in FIG. 2 in an AA′ direction. As illustrated in FIG. 1 or FIG. 2, a flexible display cover plate 10 includes a first cover plate layer 11 and a second cover plate layer 12 that are stacked along a first direction X. In FIG. 2, the first direction X is an upward direction perpendicular to the paper surface (not illustrated in FIG. 2).

The first direction X is the height direction of the flexible display cover plate 10, and may also be referred to as the thickness direction of the flexible display cover plate 10. The thicknesses, mentioned hereinafter, of film layers such as the first cover plate layer 11 and the second cover plate layer 12 all refer to the dimensions of the film layers in the first direction X.

Referring to FIG. 1 or FIG. 2, the orthographic projection of the second cover plate layer 12 on the first cover plate layer 11 completely covers the first cover plate layer 11.

The complete coverage means that the orthographic projection of the second cover plate layer 12 on the first cover plate layer 11 entirely encompasses the first cover plate layer 11, without omitting any part of the first cover plate layer 11. That is, the orthographic projection of the first cover plate layer 11 on the second cover plate layer 12 is within a region in which the second cover plate layer 12 is disposed.

Referring to FIG. 1 or FIG. 2, the second cover plate layer 12 includes a view region (view area, VA) 121, and a non-view region 122. The non-view region 122 is disposed around the view region 121. The non-view region 122 includes an ink region 122a and a non-ink region 122b. The ink region 122a is disposed between the non-ink region 122b and the view region 121. In addition, there is an overlapping area M between the orthographic projection of the non-ink region 122b on the first cover plate layer 11 and the first cover plate layer 11.

The region being disposed around the view region 121 refers to a remaining region (hereinafter referred to as a side edge region) proximal to the side edge after the view region 121 is removed from the second cover plate layer 12. That is, the non-view region 122 is the side edge region on the second cover plate layer 12. The non-view region 122 on the second cover plate layer 12 is configured to set the ink region 122a and the non-ink region 122b. The specific proportion of the view region 121 and the non-view region 122 occupying the second cover plate layer 12 is not limited in the embodiments of the present disclosure. For example, the proportion of the view region 121 and the non-view region 122 on the second cover plate layer 12 is set according to a setting range of a view region and an ink region well-known in the field.

In the embodiments of the present disclosure, the non-view region 122 on the second cover plate layer 12 includes four side edge regions on the second cover plate layer 12. The non-ink region 122b is disposed in the non-view region on the second cover plate layer 12, and the non-ink region 122b may be disposed in one or more side edge regions on the second cover plate layer 12. For example, referring to FIG. 2, the non-ink region 122b may be disposed in each of the four side edge regions on the second cover plate layer 12. In some embodiments, one side of the non-ink region 122b distal to the view region 121 is a side edge of the second cover plate layer 12. That is, the non-ink region 122b is disposed by using a part of the side edge of the second cover plate layer 12 as an edge.

Correspondingly, the first cover plate layer 11 includes a view region and a non-view region. The view region on the first cover plate layer 11 is a region in which the orthographic projection, on the first cover plate layer 11, of the view region 121 on the second cover plate layer 12 is located. The non-view region on the first cover plate layer 11 is a region around the view region. In the embodiments of the present disclosure, since there is the overlapping area M between the orthographic projection, on the first cover plate layer 11, of the non-ink region 122b on the second cover plate layer 12 and the first cover plate layer 11, and the ink region 122a is disposed between the non-ink region 122b on the second cover plate layer 12 and the view region 121, the non-view region on the first cover plate layer 11 includes a region opposite to the non-ink region 122b on the second cover plate layer 12 (i.e., the overlapping area M) and a region opposite to the ink region 122a on the second cover plate layer 12. In some embodiments, one side, distal to the view region, of the region on the first cover plate layer 11 opposite to the non-ink region 122b on the second cover plate layer 12 (i.e., the overlapping area M) is the side edge of the first cover plate layer 11.

The non-ink region 122b is disposed on the non-view region 122 of the second cover plate layer 12 to expose the side edge region of the first cover plate layer 11. The area of the second cover plate layer 12 is greater than the area of the first cover plate layer 11. Therefore, within a specific tolerance range, the area of the non-ink region 122b on the second cover plate layer 12 is not less than the area of the overlapping area M.

In the flexible display cover plate according to the embodiments of the present disclosure, the non-ink region is disposed in the side edge region of the second cover plate layer, such that there is an overlapping area between the orthographic projection, on the first cover plate layer, of the non-ink region on the second cover plate layer and the first cover plate layer. In this way, the attachment effect between the first cover plate layer and the second cover plate layer can be directly observed, whether the first cover plate layer is cracked can be found in time, and cutting of the first cover plate layer in the subsequent processing process can be avoided. The conditions of components in the flexible display cover plate are observed in real time through the non-ink regions on the second cover plate layer, such that the cutting result can be tracked more accurately.

In some embodiments, the manufacturing material of the first cover plate layer 11 includes UTG. For example, the UTG is soda-lime glass, aluminosilicate glass, soda aluminosilicate glass, lithium aluminosilicate glass, or phosphorus aluminosilicate glass.

In some embodiments, the dimension of the first cover plate layer 11 in the first direction X ranges from 0.01 mm to 0.1 mm. For example, the dimension of the first cover plate layer 11 in the first direction X is 0.01 mm, 0.03 mm, 0.05 mm, 0.08 mm, 0.1 mm, or any value in the above range.

In some embodiments, the manufacturing material of the second cover plate layer 12 includes polyimide (PI), polyethylene terephthalate (PET), or the like.

In some embodiments, the dimension of the second cover plate layer 12 in the first direction X ranges from 0.01 mm to 0.2 mm. For example, the dimension of the second cover plate layer 12 in the first direction X is 0.01 mm, 0.05 mm, 0.1 mm, 0.15 mm, 0.2 mm, or any value in the above range.

In some embodiments, continuing to refer to FIG. 1, the flexible display cover plate 10 further includes an adhesive layer 13. The adhesive layer 13 is disposed between the first cover plate layer 11 and the second cover plate layer 12.

In some embodiments, the material of the adhesive layer 13 is an adhesive bonding substance commonly used in a flexible display device. For example, the material of the adhesive layer 13 is an optical clear adhesive (OCA).

It should be understood that an adhesive layer needs to be provided between different film layers to achieve bonding. The adhesive layer may be indicated or may not be indicated in the accompanying drawings, and does not constitute a limitation on the present disclosure.

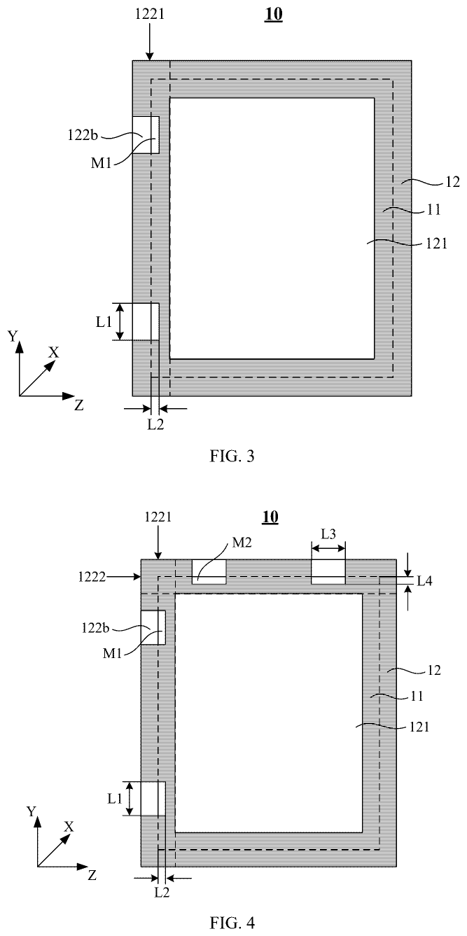

In some embodiments, FIG. 3 is a schematic structural diagram of another flexible display cover plate according to some embodiments of the present disclosure. As illustrated in FIG. 3, the non-view region 122 on the second cover plate layer 12 includes a first side edge region 1221. The first side edge region 1221 includes the non-ink region 122b. There is a first overlapping area M1 between the orthographic projection, on the first cover plate layer 11, of the non-ink region 122b in the first side edge region 1221 and the first cover plate layer 11. The dimension L1 of the non-ink region 122b in the first side edge region 1221 in a second direction Y satisfies: 0.5 mm≤L1≤20 mm. The dimension L2 of the first overlapping area M1 in a third direction Z satisfies: 0 mm<L2≤1 mm. The second direction Y is the length direction of the first side edge region 1221, and the third direction Z is the width direction of the first side edge region 1221. Any two of the first direction X, the second direction Y, and the third direction Z are perpendicular to each other.

In some embodiments, in the case that the first side edge region 1221 is the long side edge region of the second cover plate layer 12, the second direction is regarded as the length direction of the flexible display cover plate 10, and the third direction is regarded as the width direction of the flexible display cover plate 10.

It should be understood that the length and width directions are merely conclusions drawn based on the accompanying drawings and the default definitions of the length and width in a square, and do not constitute a limitation on the present disclosure. For example, in the case that the dimension of the second cover plate layer 12 in the second direction Y is less than the dimension of the second cover plate layer in the third direction Z, the second direction Y may also be referred to as the width direction of the second cover plate layer 12.

In the embodiments of the present disclosure, in the case that the non-ink region 122b is disposed in the first side edge region 1221 of the second cover plate layer 12, the dimension of the non-ink region 122b in the second direction Y ranges from 0.5 mm to 20 mm. The condition of the first cover plate layer 11 is observed in time through the non-ink region 122b of the dimension. In addition, the dimension L2, in the third direction Z, of the region (i.e., the first overlapping area M1), in which the orthographic projection, on the first cover plate layer 11, of the non-ink region 122b in the first side edge region 1221 is located, satisfies: 0 mm<L2≤1 mm; that is, the dimension of the observed first overlapping area M1 in the third direction Z is not greater than 1 mm. In this way, the specific condition of the first cover plate layer 11 can be determined, and the function of the first cover plate layer 11 as a display region is not affected, even if too much region of the first cover plate layer 11 is exposed.

In some embodiments, the dimension L1 of the non-ink region 122b on the first side edge region 1221 of the second cover plate layer 12 in the second direction Y is 0.5 mm, 3.5 mm, 10.6 mm, 15 mm, 20 mm, or any value in the above range. The dimension L2 of the first overlapping area M1 in the third direction Z is 0.2 mm, 0.4 mm, 0.6 mm, 0.8 mm, 1 mm, or any value in the above range.

In some embodiments, FIG. 4 is a schematic structural diagram of yet another flexible display cover plate according to some embodiments of the present disclosure. As illustrated in FIG. 4, the non-view region 122 on the second cover plate layer 12 further includes a second side edge region 1222 adjacent to the first side edge region 1221. The length direction of the second side edge region 1222 is the third direction Z, and the width direction of the second side edge region 1222 is the second direction Y. The second side edge region 1222 includes the non-ink region 122b. There is a second overlapping area M1 between the orthographic projection, on the first cover plate layer 11, of the non-ink region 122b in the second side edge region 1222 and the first cover plate layer 11. The dimension L3 of the non-ink region 122b in the second side edge region 1222 in the third direction Z satisfies: 0.5 mm≤L3≤20 mm. The dimension L4 of the second overlapping area M2 in the second direction Y satisfies: 0 mm<L4≤1 mm.

In the embodiments of the present disclosure, in the case that the non-ink region 122b is disposed in the second side edge region 1222 of the second cover plate layer 12, the dimension of the non-ink region 122b in the third direction Z ranges from 0.5 mm to 20 mm. The condition of the first cover plate layer 11 is observed in time through the non-ink region 122b of the dimension. In addition, the dimension L4, in the second direction Y, of the region (i.e., the second overlapping area M2), in which the orthographic projection, on the first cover plate layer 11, of the non-ink region 122b in the second side edge region 1222 is located, satisfies: 0 mm<L4≤1 mm; that is, the dimension of the observed second overlapping area M2 in the second direction Y is not greater than 1 mm. In this way, the specific condition of the first cover plate layer 11 can be determined, and the function of the first cover plate layer 11 as a display region is not affected, even if too much region of the first cover plate layer 11 is exposed.

In some embodiments, the dimension L3 of the non-ink region 122b on the second side edge region 1222 of the second cover plate layer 12 in the third direction Z is 0.5 mm, 5 mm, 10.2 mm, 16 mm, 20 mm, or any value in the above range. The dimension L4 of the second overlapping area M2 in the second direction Y is 0.2 mm, 0.4 mm, 0.6 mm, 0.8 mm, 1 mm, or any value in the above range.

It should be understood that the dimensions of the second cover plate layer 12 in the second direction Y and the third direction Z generally range from 50 mm to 500 mm, and the dimensions of the non-ink region 122b in the second direction Y and the third direction Z are as described above. Therefore, the accompanying drawings of the present disclosure enlarge the dimensions of the non-ink region 122b for illustrative purposes only, and the accompanying drawings are not used to limit an actual product.

In some embodiments, referring to FIG. 3 or FIG. 4, the second cover plate layer 12 is provided with four side edge regions. The manner of disposing the non-ink region on a side edge region opposite to the first side edge region 1221 may be the same as the manner of disposing the non-ink region on the first side edge region 1221, and the manner of disposing the non-ink region on a side edge region opposite to the second side edge region 1222 may be the same as the manner of disposing the non-ink region on the second side edge region 1222, which are not repeated in the embodiments of the present disclosure.

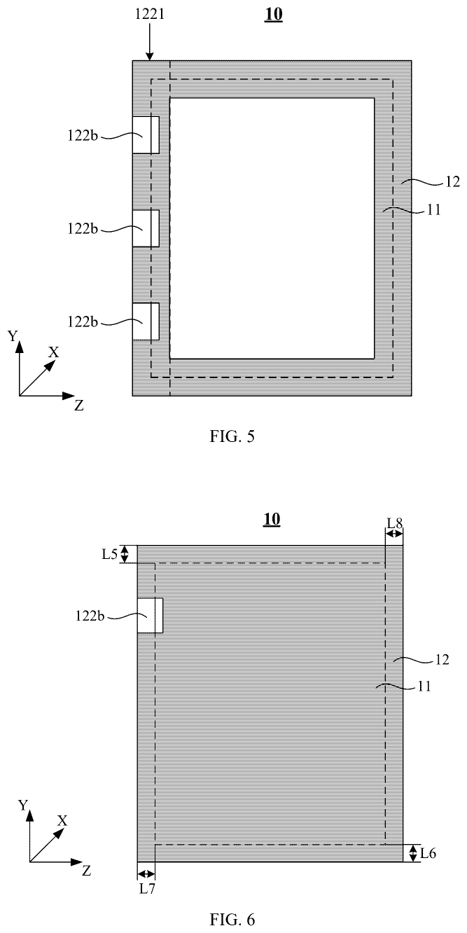

In some embodiments, FIG. 5 is a schematic structural diagram of still another flexible display cover plate according to some embodiments of the present disclosure. As illustrated in FIG. 5, the first side edge region 1221 of the second cover plate layer 12 includes a plurality of non-ink regions 122b. The plurality of non-ink regions 122b in the first side edge region 1221 are spaced apart at equal intervals along the second direction Y.

The plurality of non-ink regions 122b in the first side edge region 1221 being spaced apart at equal intervals along the second direction Y means that distances between two adjacent non-ink regions 122b in the plurality of non-ink regions 122b are equal.

In the embodiments of the present disclosure, the plurality of non-ink regions 122b are disposed at equal intervals in the same side edge region of the second cover plate layer 12, such that the condition of the first cover plate layer 11 can be more comprehensively observed.

In some embodiments, a ratio of the total dimension of the plurality of non-ink regions 122b in the first side edge region 1221 of the second cover plate layer 12 in the second direction Y to the length of the first side edge region 1221 ranges from 0.1 to 0.5. For example, the ratio of the total dimension of the plurality of non-ink regions 122b in the first side edge region 1221 of the second cover plate layer 12 in the second direction Y to the length of the first side edge region 1221 is 0.1, 0.15, 0.25, 0.4, 0.5, or any value in the above range.

In the embodiments of the present disclosure, in the case that the side edge region of the second cover plate layer 12 is provided with an excessive quantity of non-ink regions 122b, the non-ink regions are seen by a user, thereby affecting user experience. The length-dimension ratio between the non-ink regions 122b and the side edge region, in which the non-ink regions are located, is set to 0.1 to 0.5, such that the non-ink regions 122b play corresponding roles, and the user experience is prevented from being affected due to the excessive quantity of non-ink regions 122b.

Similarly, the manner of disposing the non-ink region 122b in the second side edge region 1222 of the second cover plate layer 12 may be similar to the manner of disposing the non-ink region 122b in the first side edge region 1221. In some embodiments, the second side edge region 1222 of the second cover plate layer 12 includes a plurality of non-ink regions 122b. The plurality of non-ink regions 122b in the second side edge region 1222 are spaced apart at equal intervals along the third direction Z.

In some embodiments, a ratio of the total dimension of the plurality of non-ink regions 122b in the second side edge region 1222 of the second cover plate layer 12 in the third direction Z to the length of the second side edge region 1222 ranges from 0.1 to 0.5.

In some embodiments, the non-ink region 122b is disposed on the second cover plate layer 12 at the position where a side edge spacing from the first cover plate layer 11 is minimal. It should be noted that the side edge spacing between the second cover plate layer 12 and the first cover plate layer 11 mentioned in the embodiments of the present disclosure refers to a spacing between the second cover plate layer and the first cover plate layer in the second direction Y or the third direction Z on the same side.

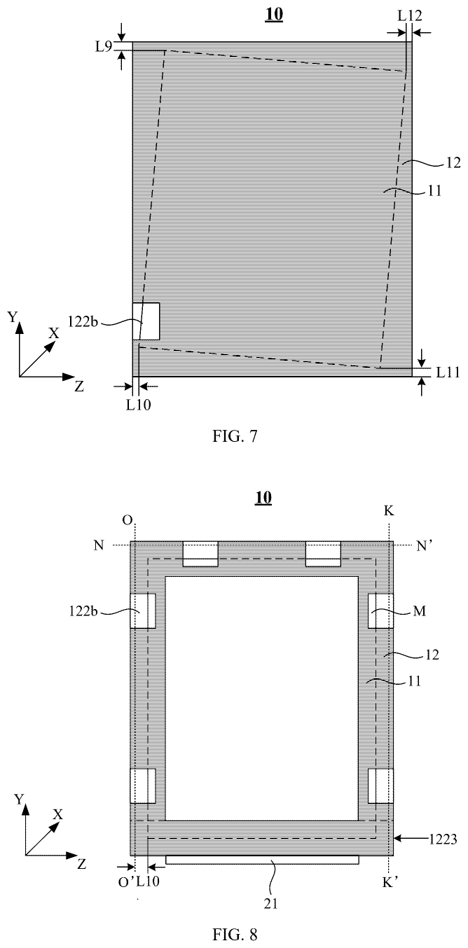

For example, FIG. 6 is a schematic structural diagram of a flexible display cover plate according to some embodiments of the present disclosure. As illustrated in FIG. 6, the side edge of the first cover plate layer 11 is parallel to the side edge of the second cover plate layer 12; that is, four side edges of the first cover plate layer 11 are parallel to four side edges of the second cover plate layer 12, respectively. There are four different side edge spacings L5, L6, L7, and L8 between the side edges of the second cover plate layer 12 and the side edges of the first cover plate layer 11. Referring to FIG. 6, assuming that L7 is the smallest among L5, L6, L7, and L8, the non-ink region 122b may be disposed in a side edge region on the second cover plate layer 12 with a side edge spacing of L7 from the first cover plate layer 11. Similarly, in the case that L6 is the smallest among L5, L6, L7, and L8, the non-ink region 122b may be disposed in a side edge region on the second cover plate layer 12 with a side edge spacing of L6 from the first cover plate layer 11.

For example, FIG. 7 is a schematic structural diagram of another flexible display cover plate according to some embodiments of the present disclosure. As illustrated in FIG. 7, the side edges of the first cover plate layer 11 are inclined with respect to the side edges of the second cover plate layer 12; that is, four side edges of the first cover plate layer 11 are all not parallel to four side edges of the second cover plate layer 12. There are four different side edge spacings L9, L10, L11, and L12 between the side edges of the second cover plate layer 12 and the side edges of the first cover plate layer 11. Referring to FIG. 7, assuming that L10 is the smallest among L9, L10, L11, and L12, the non-ink region 122b may be disposed in a side edge region on the second cover plate layer 12 with a side edge spacing of L10 from the first cover plate layer 11. Similarly, in the case that L11 is the smallest among L9, L10, L11, and L12, the non-ink region 122b may be disposed in a side edge region on the second cover plate layer 12 with a side edge spacing of L11 from the first cover plate layer 11. It should be understood that the side edge spacing here refers to the shortest distance between the side edges of the first cover plate layer 11 and the second cover plate layer 12 on the same side.

In the embodiments of the present disclosure, due to the existence of the non-ink region 122b on the second cover plate layer 12, a part of the edge region (the overlapping area M described above) of the first cover plate layer 11 is observed. During the processing process of the flexible display cover plate 10, the precursor of the flexible display cover plate 10 (the flexible display cover plate motherboard) is cut, while ensuring that the first cover plate layer 11 is not cut. The non-ink region 122b is disposed on the second cover plate layer 12 at the position where a side edge spacing from the first cover plate layer 11 is minimal, such that an edge region that is most easily cut by mistake on the first cover plate layer 11 can be observed, thereby more accurately observing the condition of the first cover plate layer 11 during cutting, and reducing the risk of cutting the first cover plate layer 11 by mistake.

In some embodiments, a distance from the non-ink region 122b on the second cover plate layer 12 to the vertex of the second cover plate layer 12 is less than a preset distance. That is, the non-ink region 122b may be disposed in the side edge region of the second cover plate layer 12 at a position proximal to the vertex of the second cover plate layer 12. For example, the non-ink region 122b is disposed at the position at a certain distance from the vertex of the second cover plate layer 12, but the distance is less than a distance from the non-ink region 122b to the middle of the second cover plate layer 12. Within a specific tolerance range, the non-ink region 122b on the second cover plate layer 12 may also include the vertex of the second cover plate layer 12.

In the embodiments of the present disclosure, the non-ink region 122b on the second cover plate layer 12 is configured to observe the breakage of the first cover plate layer 11 and accurately track the subsequent cutting condition. Since the vertex position of the second cover plate layer 12 is easier to break than the central position of the second cover plate layer, the non-ink region 122b is disposed in the side edge region of the second cover plate layer 12 at the position proximal to the vertex of the second cover plate layer 12, such that the side edge position of the first cover plate layer 11 can be observed more conveniently.

In some embodiments, the flexible display cover plate 10 is provided with a bending region, and the non-ink region 122b on the second cover plate layer 12 is disposed in a region other than the bending region. That is, the non-ink region 122b on the second cover plate layer 12 is disposed to avoid the bending region.

In the embodiments of the present disclosure, the flexible display cover plate 10 has a folding function. The flexible display cover plate 10 is provided with a bending region, to fold the flexible display cover plate 10. A shielding structural member at the edge of the bending region moves along with the bending process of the flexible display cover plate 10. By disposing the non-ink region 122a to avoid the bending region, the risk of exposure of the non-ink region 122a can be reduced.

In some embodiments, FIG. 8 is a schematic structural diagram of yet another flexible display cover plate according to some embodiments of the present disclosure. As illustrated in FIG. 8, the non-view region 122 on the second cover plate layer 12 includes a lead-out side edge region 1223. The lead-out side edge region 1223 is configured to connect to a lead-out region 21 of a display device. The non-ink region 122b may not be disposed in the lead-out side edge region 1223.

In the actual production process of the display device, laser cutting needs to be performed on the precursor of the flexible display cover plate 10, to obtain the flexible display cover plate 10 described in the embodiments of the present disclosure. Laser cutting lines OO′, NN′, and KK′ are illustrated in FIG. 8. In the production process, according to the production requirements of some display devices, a certain side edge region of the second cover plate layer 12 needs to be reserved, such that the lead-out region 21 of the display device can be correspondingly disposed in the side edge region (FIG. 8 is merely an accompanying drawing illustrating that the lead-out region 21 is disposed on the flexible display cover plate 10, and actually, the lead-out region is not a component in the flexible display cover plate 10). The side edge region is the lead-out side edge region 1223.

In some embodiments, the lead-out side edge region 1223 on the second cover plate layer 12 is any side edge region on the second cover plate layer 12. For example, the lead-out side edge region is the first side edge region 1221 described above, or is another side edge region, which is not limited in the embodiments of the present disclosure.

In the embodiments of the present disclosure, the lead-out side edge region 1223 is reserved on the second cover plate layer 12 for connection to the lead-out region 21 of the display device, thereby ensuring the normal operation of the display device. In addition, since the lead-out side edge region 1223 does not need to be cut, the non-ink region 122b may not be disposed in the lead-out side edge region 1223.

In some embodiments, the non-view region 122 on the second cover plate layer 12 includes a non-lead-out side edge region. A side edge spacing between the non-lead-out side edge region and the first cover plate layer 11 ranges from 0.05 mm to 1 mm. The non-ink region 122b is disposed in the non-lead-out side edge region. For example, the side edge spacing between the non-lead-out side edge region on the second cover plate layer 12 and the first cover plate layer 11 is 0.05 mm, 0.06 mm, 0.1 mm, 0.5 mm, 1 mm, or any value in the above range.

It should be noted that side edge regions on the second cover plate layer 12 other than the lead-out side edge region are all non-lead-out side edge regions. For example, in the flexible display cover plate 10 illustrated in FIG. 8, side edge regions on the second cover plate layer 12 other than the lead-out side edge region 1223 are all non-lead-out side edge regions. A side edge spacing L10 between one of the non-lead-out side edge regions and the first cover plate layer 11 ranges from 0.05 mm to 1 mm.

It should be understood that the side edge spacing between the non-lead-out side edge region on the second cover plate layer 12 and the first cover plate layer 11 refers to a distance between the side edge of a side where the non-lead-out side edge region on the second cover plate layer 12 is located, and a side edge on the first cover plate layer 11 that is parallel to and on the same side as the side edge.

Continuing to refer to FIG. 8, in the manufacturing process of the flexible display cover plate 10, the precursor of the flexible display cover plate 10 is cut along the laser cutting lines OO′, NN′, and KK′. To observe in time whether the first cover plate layer 11 is cut during laser cutting, the non-ink region 122b may be first disposed on the second cover plate layer 12, then the second cover plate layer 12 and the first cover plate layer 11 are bonded, and finally, laser cutting is performed. It should be noted that the process steps are not particularly limited in the embodiments of the present disclosure. It should be noted that in the case that the second cover plate layer 12 is obtained by laser cutting, the side edge region of the second cover plate layer 12 mentioned in the embodiments of the present disclosure refers to a cut side edge region of the second cover plate layer 12.

In the embodiments of the present disclosure, the first cover plate layer 11 is disposed below the second cover plate layer 12, and the orthographic projection of the second cover plate layer 12 on the first cover plate layer 11 completely covers the first cover plate layer 11. The side edge spacing between the non-lead-out side edge region on the second cover plate layer 12 and the first cover plate layer 11 is kept between 0.05 mm and 1 mm, such that the second cover plate layer 12 can effectively protect the first cover plate layer 11.

In some embodiments, the shape of the non-ink region 122b on the second cover plate layer 12 includes at least one of a rectangle, a circle, an ellipse, a rhombus, or a trapezoid.

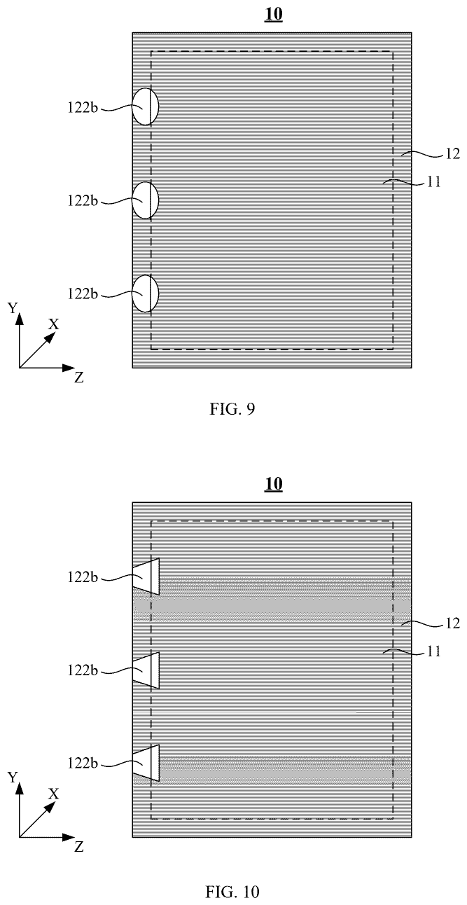

For example, FIGS. 9 and 10 are schematic structural diagrams of a flexible display cover plate according to some embodiments of the present disclosure, respectively. As illustrated in FIG. 9, the shape of the non-ink region 122b on the second cover plate layer 12 is an ellipse. Alternatively, as illustrated in FIG. 10, the shape of the non-ink region 122b on the second cover plate layer 12 is a trapezoid. Alternatively, as illustrated in any one of FIGS. 2 to 8, the shape of the non-ink region 122b on the second cover plate layer 12 is a rectangle. The shape of the non-ink region 122b on the second cover plate layer 12 is not limited in the embodiments of the present disclosure, provided that the first cover plate layer 11 can be observed through the non-ink region. The appropriate shape can be selected based on an actual requirement.

It should be noted that in the embodiments of the present disclosure, the non-ink region 122b is disposed in one or more side edge regions of the second cover plate layer 12. For example, referring to FIG. 3, the non-ink region 122b may be disposed in only one side edge region of the second cover plate layer 12. For another example, referring to FIG. 4, the non-ink regions 122b may be disposed in two side edge regions of the second cover plate layer 12, respectively. For yet another example, referring to FIG. 8, the non-ink regions 122b may be disposed in three side edge regions of the second cover plate layer 12, respectively. For still another example, referring to FIG. 2, the non-ink regions 122b may be disposed in four side edge regions of the second cover plate layer 12, respectively. In the actual production process, the non-ink region 122b may be disposed at any position in the side edge region of the second cover plate layer 12 based on an observation requirement. The position at which the non-ink region 122b is disposed on the second cover plate layer 12 is not limited in the embodiments of the present disclosure.

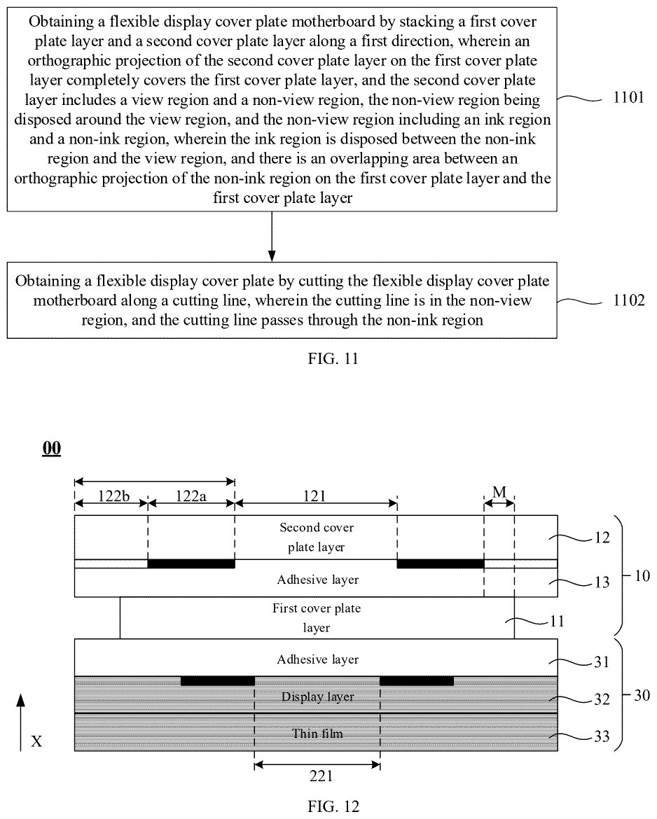

FIG. 11 is a schematic flowchart of a method for manufacturing a flexible display cover plate according to some embodiments of the present disclosure. As illustrated in FIG. 11, the method includes the following steps 1101 and 1102.

In step 1101, a flexible display cover plate motherboard is obtained by stacking a first cover plate layer and a second cover plate layer along a first direction, wherein an orthographic projection of the second cover plate layer on the first cover plate layer completely covers the first cover plate layer, and the second cover plate layer includes a view region and a non-view region, the non-view region being disposed around the view region, and the non-view region including an ink region and a non-ink region, wherein the ink region is disposed between the non-ink region and the view region, and there is an overlapping area between an orthographic projection of the non-ink region on the first cover plate layer and the first cover plate layer.

In some embodiments, before the first cover plate layer and the second cover plate layer are stacked along the first direction, an ink layer is formed on the provided cover plate motherboard, and a window is formed in the ink layer on the cover plate motherboard to form the ink region and the non-ink region, thereby obtaining the first cover plate layer.

In step 1102, the flexible display cover plate motherboard is cut along a cutting line to obtain a flexible display cover plate. The cutting line is in the non-view region, and the cutting line passes through the non-ink region.

In some embodiments, the flexible display cover plate motherboard is cut along the cutting line by laser cutting. For the position of the cutting line, reference is made to, for example, the positions of the cutting lines OO′, NN′, and KK′ as illustrated in FIG. 8.

In the method for manufacturing a flexible display cover plate according to the embodiments of the present disclosure, the non-ink region is disposed in the side edge region of the second cover plate layer, such that there is an overlapping area between the orthographic projection, on the first cover plate layer, of the non-ink region on the second cover plate layer and the first cover plate layer. In this way, the attachment effect between the first cover plate layer and the second cover plate layer can be directly observed, whether the first cover plate layer is cracked can be found in time, and cutting of the first cover plate layer in the processing process can be avoided. The conditions of components in the flexible display cover plate are observed in real time through the non-ink regions on the second cover plate layer, such that the cutting result can be tracked more accurately.

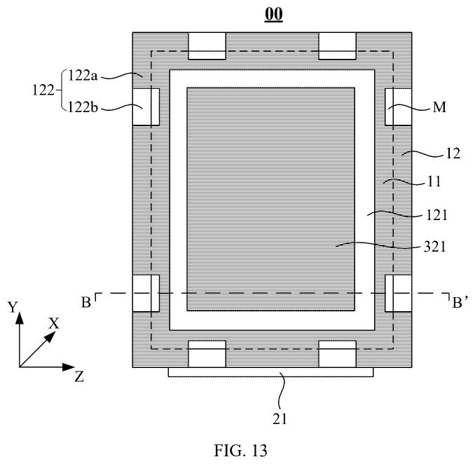

The embodiments of the present disclosure further provide a displaying module. The displaying module includes the flexible display cover plate 10 described in any one of the above embodiments. For example, FIGS. 12 and 13 are schematic structural diagrams of a displaying module according to some embodiments of the present disclosure, respectively. FIG. 12 is a schematic cross-sectional diagram of the displaying module illustrated in FIG. 13 in a BB′ direction. As illustrated in FIG. 12, the displaying module 00 includes the flexible display cover plate 10 illustrated in FIG. 1. As illustrated in FIG. 13, the displaying module 00 includes the flexible display cover plate 10 illustrated in FIG. 2.

In some embodiments, the displaying module 00 further includes a display substrate 30. Continuing to refer to FIG. 12, the flexible display cover plate 10 is disposed on the display substrate 30, and one surface, distal to the second cover plate layer 12, of the first cover plate layer 11 in the flexible display cover plate 10 is attached to the display substrate 30. In some embodiments, the flexible display cover plate 10 is fixedly attached to the display substrate 30 through an adhesive layer 31.

In some embodiments, continuing to refer to FIG. 12, the display substrate 30 includes a display layer 32 and a thin film 33. The display layer 32 includes an active region (active area, AA) 321.

In some embodiments, continuing to refer to FIG. 13, the display substrate 30 further includes a lead-out region 21.

The embodiments of the present disclosure further provide a display device. The display device includes the displaying module 30 described in any one of the above embodiments. The display device may be, for example, an organic light-emitting diode (OLED) display.

In some embodiments, the product form of the above display device includes, but is not limited to: a computer display, a television, a billboard, a laser printer with a display function, a phone, a mobile phone, a personal digital assistant (PDA), a laptop computer, a digital camera, a portable camcorder, a viewfinder, a vehicle, a large-area wall, a screen of a theater, a stadium sign, or the like.

It should be noted that relational terms used herein, such as first and second, are merely used to distinguish one entity or operation from another entity or operation without necessarily requiring or implying any such actual relationship or order between such entities or operations. Moreover, the terms “includes”, “including”, or any other variation thereof, are intended to encompass a non-exclusive inclusion, such that a process, method, item, or device that includes a list of elements does not include only those elements but also include other elements not expressly listed or elements inherent to such process, method, item, or device. Without further limitation, an element defined by the phrase “including a . . . ” does not exclude the presence of additional identical elements in the process, method, item, or device that includes the element.

The embodiments herein are described in a related manner, and the same and similar parts among the embodiments may be referred to each other, and each embodiment focuses on differences from the other embodiments. Especially, since the system embodiments are substantially similar to the method embodiments, the description is relatively simple, and reference may be made to the description of the method embodiment part.

The present disclosure is not limited to the above embodiments. The embodiments described above are merely examples, and any embodiments having a structure substantially identical to the technical concept and exerting the same functional effects within the scope of the technical solutions of the present disclosure are all included within the technical scope of the present disclosure. Furthermore, without departing from the spirit of the present disclosure, various modifications that can be conceived by those skilled in the art to the embodiments, as well as other embodiments constructed by combining part of the constituent elements of the embodiments, are also included within the scope of the present disclosure.

1. A flexible display cover plate, comprising:
a first cover plate layer and a second cover plate layer that are stacked along a first direction, wherein an orthographic projection of the second cover plate layer on the first cover plate layer completely covers the first cover plate layer; and
the second cover plate layer comprises a view region and a non-view region, the non-view region being disposed around the view region and the non-view region comprising an ink region and a non-ink region,
wherein the ink region is disposed between the non-ink region and the view region, and there is an overlapping area between an orthographic projection of the non-ink region on the first cover plate layer and the first cover plate layer.

2. The flexible display cover plate according to claim 1, wherein the non-view region comprises a first side edge region, wherein the first side edge region comprises the non-ink region, and there is a first overlapping area between an orthographic projection, on the first cover plate layer, of the non-ink region in the first side edge region and the first cover plate layer; and
a dimension L1 of the non-ink region in the first side edge region in a second direction satisfies: 0.5 millimeters (mm)≤L1≤20 mm, and a dimension L2 of the first overlapping area in a third direction satisfies: 0 mm<L2≤1 mm,
wherein the second direction is a length direction of the first side edge region, the third direction is a width direction of the first side edge region, and any two of the first direction, the second direction, and the third direction are perpendicular to each other.

3. The flexible display cover plate according to claim 2, wherein the first side edge region comprises a plurality of non-ink regions, the plurality of non-ink regions in the first side edge region being spaced apart at equal intervals along the second direction.

4. The flexible display cover plate according to claim 3, wherein a ratio of a total dimension of the plurality of non-ink regions in the first side edge region in the second direction to a length of the first side edge region ranges from 0.1 to 0.5.

5. The flexible display cover plate according to claim 2, wherein the non-view region further comprises a second side edge region adjacent to the first side edge region, wherein a length direction of the second side edge region is the third direction, a width direction of the second side edge region is the second direction, the second side edge region comprises the non-ink region, and there is a second overlapping area between an orthographic projection, on the first cover plate layer, of the non-ink region in the second side edge region and the first cover plate layer; and
a dimension L3 of the non-ink region in the second side edge region in the third direction satisfies: 0.5 mm≤L3≤20 mm, and a dimension L4 of the second overlapping area in the second direction satisfies: 0 mm<L4≤1 mm.

6. The flexible display cover plate according to claim 5, wherein the second side edge region comprises a plurality of non-ink regions, the plurality of non-ink regions in the second side edge region being spaced apart at equal intervals along the third direction.

7. The flexible display cover plate according to claim 6, wherein a ratio of a total dimension of the plurality of non-ink regions in the second side edge region in the third direction to a length of the second side edge region ranges from 0.1 to 0.5.

8. The flexible display cover plate according to claim 1, wherein the non-ink region is disposed on the second cover plate layer at a position where a side edge spacing from the first cover plate layer is minimal.

9. The flexible display cover plate according to claim 1, wherein a distance from the non-ink region to a vertex of the second cover plate layer is less than a preset distance.

10. The flexible display cover plate according to claim 1, wherein the flexible display cover plate is provided with a bending region, and the non-ink region is disposed in a region other than the bending region.

11. The flexible display cover plate according to claim 1, wherein the non-view region comprises a lead-out side edge region, the lead-out side edge region being configured to connect to a lead-out region of a display device.

12. The flexible display cover plate according to claim 1, wherein the non-view region comprises a non-lead-out side edge region, wherein a side edge spacing between the non-lead-out side edge region and the first cover plate layer ranges from 0.05 mm to 1 mm, and the non-ink region is disposed in the non-lead-out side edge region.

13. The flexible display cover plate according to claim 1, further comprising an adhesive layer, the adhesive layer being disposed between the first cover plate layer and the second cover plate layer.

14. The flexible display cover plate according to claim 1, wherein a shape of the non-ink region comprises at least one of a rectangle, a circle, an ellipse, a rhombus, or a trapezoid.

15. The flexible display cover plate according to claim 1, wherein a manufacturing material of the first cover plate layer comprises ultra-thin glass.

16. A method for manufacturing a flexible display cover plate, comprising:
obtaining a flexible display cover plate motherboard by stacking a first cover plate layer and a second cover plate layer along a first direction, wherein an orthographic projection of the second cover plate layer on the first cover plate layer completely covers the first cover plate layer, and the second cover plate layer comprises a view region and a non-view region, the non-view region being disposed around the view region, and the non-view region comprising an ink region and a non-ink region, wherein the ink region is disposed between the non-ink region and the view region, and there is an overlapping area between an orthographic projection of the non-ink region on the first cover plate layer and the first cover plate layer; and
obtaining a flexible display cover plate by cutting the flexible display cover plate motherboard along a cutting line, wherein the cutting line is in the non-view region, and the cutting line passes through the non-ink region.

17. The manufacturing method according to claim 16, wherein before stacking the first cover plate layer and the second cover plate layer along the first direction, the method further comprises:
providing a cover plate motherboard;
forming an ink layer on the cover plate motherboard; and
forming a window in the ink layer on the cover plate motherboard to form the ink region and the non-ink region, thereby obtaining the first cover plate layer.

18. A displaying module, comprising a flexible display cover plate;
wherein the flexible display cover plate, comprises:
a first cover plate layer and a second cover plate layer that are stacked along a first direction, wherein an orthographic projection of the second cover plate layer on the first cover plate layer completely covers the first cover plate layer; and
the second cover plate layer comprises a view region and a non-view region, the non-view region being disposed around the view region, and the non-view region comprising an ink region and a non-ink region,
wherein the ink region is disposed between the non-ink region and the view region, and there is an overlapping are between an orthographic projection of the non-ink region on the first cover plate layer and the first cover plate layer.

19. The displaying module according to claim 18, further comprising a display substrate, wherein
the flexible display cover plate is disposed on the display substrate, and one surface, distal to the second cover plate layer, of the first cover plate layer in the flexible display cover plate is attached to the display substrate.

20. A display device, comprising the displaying module as defined in claim 18.
